(19) United States
(12) Patent Application Publication
(10) Pub. No.: US 2011/0291113 A1
(43) Pub. Date: Dec. 1, 2011

(54) FILTER FOR A LIGHT EMITTING DEVICE

(75) Inventor: Danielle R. CHAMBERLIN, Belmont, CA (US)

(73) Assignees: PHILIPS LUMILEDS LIGHTING COMPANY, LLC, SAN JOSE, CA (US); KONINKLIJKE PHILIPS ELECTRONICS N.V., EINDHOVEN (NL)

(21) Appl. No.: 12/788,762

(22) Filed: May 27, 2010

(51) Int. Cl. H01L 33/48; H01L 33/60

(52) U.S. Cl. 257/88; 257/98; 977/950; 257/E33.059; 257/E33.067

(57) ABSTRACT

Embodiments of the invention include a semiconductor light emitting device capable of emitting first light having a first peak wavelength and a wavelength converting element capable of absorbing the first light and emitting second light having a second peak wavelength. In some embodiments, the structure further includes a metal nanoparticle array configured to pass a majority of light in a first wavelength range and reflect or absorb a majority of light in a second wavelength range. In some embodiments, the structure further includes a filter configured to pass a majority of light in a first wavelength range and reflect or absorb a majority of light in a second wavelength range, wherein the filter is configured such that a wavelength at which a minimum amount of light is passed by the filter shifts no more than 30 nm for light incident on the filter at angles between 0° and 60° relative to a normal to a major surface of the filter.

### BACKGROUND

1. Field of Invention

The present invention relates to a filter for a semiconductor light emitting device.

2. Description of Related Art

Semiconductor light-emitting devices including light emitting diodes (LEDs), resonant cavity light emitting diodes (RCLEDs), vertical cavity laser diodes (VCSELs), and edge emitting lasers are among the most efficient light sources currently available. Materials systems currently of interest in the manufacture of high-brightness light emitting devices capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a sapphire, silicon carbide, III-nitride, or other suitable substrate by metal-organic chemical vapor deposition (MOCVD), molecular beam epitaxy (MBE), or other epitaxial techniques. The stack often includes one or more n-type layers doped with, for example, Si, formed over the substrate, one or more light emitting layers in an active region formed over the n-type layer or layers, and one or more p-type layers doped with, for example, Mg, formed over the active region. Electrical contacts are formed on the n- and p-type regions.

FIG. 1 illustrates an LED described in more detail in U.S. Pat. No. 5,813,752. A short wavepass (SWP) filter 38 is disposed between the LED 36 and the phosphor layer 40, and another SWP filter 42 is added on the top (viewing side) of the phosphor layer 40. The functions of SWP filter 42 are: (1) to reflect light of too long wavelengths and (2) to reflect part of the light of the wanted wavelengths. Without the filter, this latter light exits into air at both small and large angles to the normal (with the so-called Lambertian or cosine distribution). With the filter, the large-angle light is reflected by the filter and subsequently scattered, angularly redistributed and back-reflected by the phosphor layer 40 and the filter 38 to the filter 42. A significant part of this light can then exit into air at small angles to the normal on the surface. The preferred SWP filters are multilayer dielectric stacks with alternatingly high and low refractive index with preferably at least 12 layers.

### SUMMARY

It is an object of the invention to provide a filter for a wavelength converted semiconductor light emitting device, which may improve control of color vs. angle in the spectrum emitted by the structure.

Embodiments of the invention include a semiconductor light emitting device capable of emitting first light having a first peak wavelength and a wavelength converting element capable of absorbing the first light and emitting second light having a second peak wavelength. In some embodiments, the structure further includes a metal nanoparticle array configured to pass a majority of light in a first wavelength range and reflect or absorb a majority of light in a second wavelength range. In some embodiments, the structure further includes a filter configured to pass a majority of light in a first wavelength range and reflect or absorb a majority of light in a second wavelength range, wherein the filter is configured such that a wavelength at which a minimum amount of light is passed by the filter shifts no more than 30 nm for light incident on the filter at angles between 0° and 60° relative to a normal to a major surface of the filter.

In conventional filters such as conventional dielectric stacks, the reflectance behavior of the filter is strongly dependent on the incidence angle of the light. The filters described herein may have less reflectance vs. angle dependence or different reflectance vs. angle behavior, which may offer superior color vs. angle control in the spectrum of light emitted by the structure.

### BRIEF DESCRIPTION OF THE DRAWINGS

FIG. 1 illustrates a prior art device including an LED, a phosphor layer, and two filters.

FIG. 2 illustrates an arrangement of a semiconductor light emitting device, wavelength converting element, and filter.

FIG. 3 illustrates an alternative arrangement of a semiconductor light emitting device, wavelength converting element, and filter.

FIG. 4 illustrates the path of light through a wavelength converting element disposed on a semiconductor light emitting device.

FIG. 5 illustrates a thin film flip chip light emitting device.

FIG. 6 illustrates a vertical light emitting device.

FIG. 7 illustrates a metal nanoparticle array.

FIG. 8 is a plot of extinction as a function of wavelength for silver nanocylinder arrays of various lattice spacings.

FIG. 9 is a plot of extinction as a function of wavelength for silver nanocylinder arrays of various nanocylinder diameters.

FIG. 10 is a plot of transmittance as a function of wavelength for light of various incidence angles on a gold nanoparticle array.

FIG. 11 is a plot of index ratio as a function of smaller index for stacks of two materials with different refractive indices.

### DETAILED DESCRIPTION

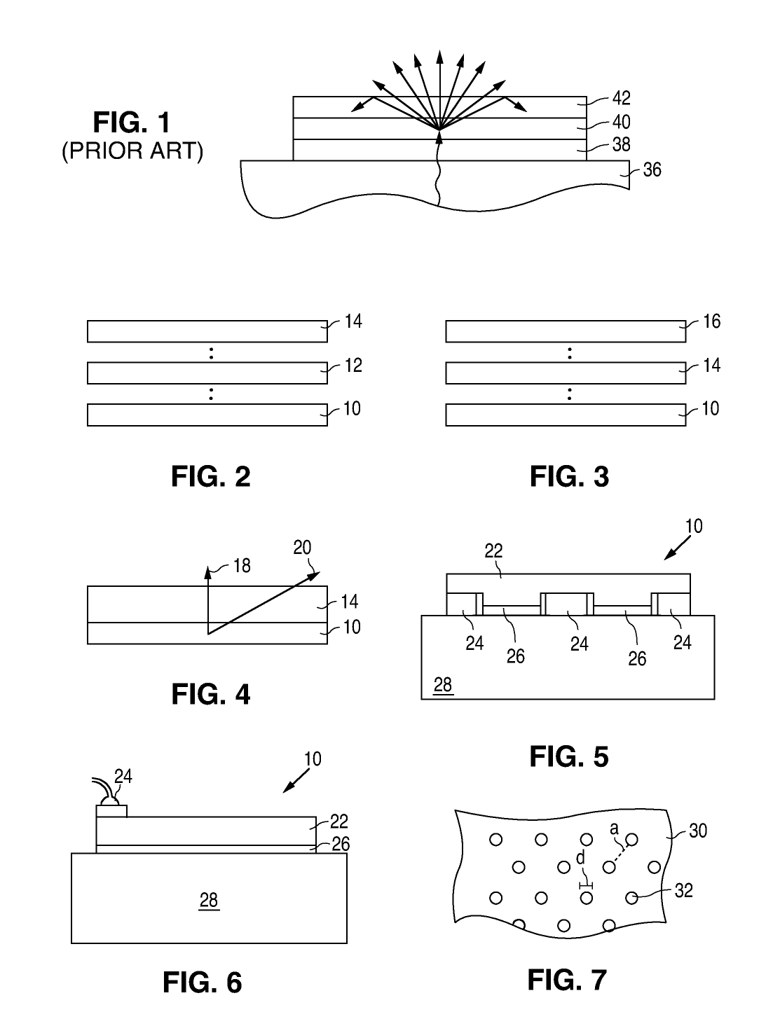

In conventional reflectors such as the multilayer dielectric stacks described above in reference to FIG. 1, the reflectance may change drastically for different incidence angles. This behavior is illustrated by the light rays shown in FIG. 1—small angle light is transmitted, while large angle light is reflected. Such reflectors are unsuitable for applications where angular dependence of the reflectance is undesirable.

In embodiments of the invention, an omnidirectional, wavelength-tunable filter is combined with a semiconductor light emitting device such as an LED for color control. The filter may be configured to pass certain wavelengths and reflect other wavelengths (wavelength-tunable) regardless of the incidence angle of either passed or reflected light (omnidirectional).

Though in the examples below the semiconductor light emitting device is a III-nitride LED that emits blue or UV light, semiconductor light emitting devices besides LEDs such as laser diodes and semiconductor light emitting devices made from other materials systems such as other III-V materials, III-phosphide, III-arsenide, II-VI materials, or Si-based materials may be used.

Any suitable LED may be used. FIGS. 5 and 6 illustrate two examples of suitable LEDs 10. To make the devices illustrated in FIGS. 5 and 6, a semiconductor structure 22 is grown over a growth substrate. The semiconductor structure 22 includes a light emitting or active region sandwiched between n- and p-type regions. An n-type region is typically grown first and may include multiple layers of different compositions and dopant concentration including, for example, preparation layers such as buffer layers or nucleation layers, which may be n-type or not intentionally doped, and n- or even p-type device layers designed for particular optical or electrical properties desirable for the light emitting region to efficiently emit light. A light emitting or active region is grown over the n-type region. Examples of suitable light emitting regions include a single thick or thin light emitting layer, or a multiple quantum well light emitting region including multiple thin or thick light emitting layers separated by barrier layers. A p-type region is grown over the light emitting region. Like the n-type region, the p-type region may include multiple layers of different composition, thickness, and dopant concentration, including layers that are not intentionally doped, or n-type layers.

In the device illustrated in FIG. 5, p-contact metal 26 is disposed on the p-type region, then portions of the p-type region and active region are etched away to expose an n-type layer for metallization. The p-contacts 26 and n-contacts 24 are on the same side of the device. As illustrated in FIG. 5, p-contacts 26 may be disposed between multiple n-contact regions 24, though this is not necessary. In some embodiments either or both the n-contact 24 and the p-contact 26 are reflective and the device is mounted such that light is extracted through the top of the device in the orientation illustrated in FIG. 5. In some embodiments, the contacts may be limited in extent or made transparent, and the device may be mounted such that light is extracted through the surface on which the contacts are formed. The semiconductor structure is attached to a mount 28. The growth substrate may be removed, as illustrated in FIG. 5, or it may remain part of the device. In some embodiments, the semiconductor layer exposed by removing the growth substrate is patterned or roughened, which may improve light extraction from the device.

In the vertical injection LED illustrated in FIG. 6, an n-contact is formed on one side of the semiconductor structure, and a p-contact is formed on the other side of the semiconductor structure. For example, the p-contact 26 may be formed on the p-type region and the device may be attached to mount 28 through p-contact 26. All or a portion of the substrate may be removed and an n-contact 24 may be formed on a surface of the n-type region exposed by removing a portion of the substrate. Electrical contact to the n-contact may be made with a wire bond as illustrated in FIG. 6 or any other suitable structure.

The LED may be combined with one or more wavelength converting materials such as phosphors, quantum dots, semiconductor quantum wells, or dyes to create white light or monochromatic light of other colors. The wavelength converting materials absorb light emitted by the LED and emit light of a different wavelength. All or only a portion of the light emitted by the LED may be converted by the wavelength converting materials. Unconverted light emitted by the LED may be part of the final spectrum of light, though it need not be. Examples of common combinations include a blue-emitting LED combined with a yellow-emitting phosphor, a blue-emitting LED combined with green- and red-emitting phosphors, a UV-emitting LED combined with blue- and yellow-emitting phosphors, and a UV-emitting LED combined with blue-, green-, and red-emitting phosphors. Wavelength converting materials emitting other colors of light may be added to tailor the spectrum of light emitted from the device. In some embodiments where a red-emitting phosphor and a green- or yellow-emitting phosphor are combined with a blue-emitting LED, the red-emitting phosphor may be disposed between the blue-emitting LED and the green- or yellow-emitting phosphor. For example, the red-emitting phosphor may be a powder and the green- or yellow-emitting phosphor may be a ceramic, such that the powder is disposed between the LED and the ceramic. Or, the red-emitting phosphor may be a ceramic and the green- or yellow-emitting phosphor may be a powder, such that the powder is disposed over the ceramic.

The wavelength converting element may be, for example, a pre-formed ceramic phosphor layers that is glued or bonded to the LED or spaced apart from the LED, or a powder phosphor or quantum dots disposed in an organic encapsulant that is stenciled, screen printed, sprayed, sedimented, evaporated, sputtered, or otherwise dispensed over the LED. In some embodiments, the wavelength converting element may be epitaxially-grown semiconductor layers, grown on the LED or grown on a separate growth substrate. Unlike the active region of the LED, which is electrically pumped, meaning that it emits light when forward biased, a semiconductor wavelength converting element is optically pumped, meaning that it absorbs light of a first wavelength and in response emits light of a second, longer wavelength.

FIG. 2 illustrates an arrangement of a light emitting device, wavelength converting element, and filter according to embodiments of the invention. A filter 12 is disposed between a semiconductor light emitting device 10 and a wavelength converting element 14. Filter 12 may be configured to allow photons at wavelengths emitted by device 10 to pass and to reflect photons at longer wavelengths, such as the wavelengths emitted by wavelength converting element 14. Filter 12 may reduce the number of photons absorbed by device 10 or by a package in or on which device 10 is mounted, which may increase the luminous efficacy of the system.

In some embodiments, filter 12 is disposed on a top surface of device 10 or on a bottom surface of a wavelength converting element that is fabricated separately from device 10, such as a ceramic phosphor.

FIG. 3 illustrates an alternative arrangement of a light emitting device, wavelength converting element, and filter according to embodiments of the invention. In the arrangement illustrated in FIG. 3, wavelength converting element 14 is disposed between light emitting device 10 and a filter 16.

In some embodiments, filter 16 is configured to partially reflect light emitted by device 10 and to pass longer wavelength light, such as light emitted by wavelength converting element 14. For example, filter 16 may be configured to reflect light emitted by device 10 at small incidence angles (for example, less than 45° relative to a normal to the top surface of the device) and pass light emitted by device 10 at large incidence angles (for example, greater than 45° relative to a normal to the top surface of the device)—the opposite of SWP filter 42 of FIG. 1, which passes light at small incidence angles and reflects light at large incidence angles. A filter 16 that reflects light emitted by device 10 at small incidence angles and passes light emitted by device 10 at large incidence angles may reduce the appearance of a halo, an effect that is illustrated in FIG. 4. In the device of FIG. 4, light 18 emitted from device 10 at small incidence angles “sees” less of wavelength converting element 14 and is therefore less likely to be converted than light 20 emitted from device 10 at large incidence angles. In the case of a blue-emitted device 10 and a yellow-emitting wavelength converting element 14, when viewed from above, light from the center of the structure will appear more blue than light from the edge, which appears more yellow, giving the appearance of a yellow “halo” around the device. Reflecting light emitted by device 10 at small angles gives that light more opportunities to be wavelength converted before escaping the structure, which may improve the color uniformity of light emitted by the structure.

Filter 16 may be configured to re-radiate light emitted by device 10 that is passed by filter 16 in, for example, a Lambertian or quasi-Lambertian pattern, which may reduce intensity variation of light emitted by device 10 as a function of incidence angle. For example, this may be accomplished by placing filter 16 on, for example, a ceramic phosphor wavelength converting element 14.

In some embodiments, filter 12 of FIG. 2 or filter 16 of FIG. 3 may be an array of nanoparticles made from noble metals. FIG. 7 illustrates such an array. The array includes areas of a first material 32 separated by a second material 30, where the first material and the second material have different indices of refraction. In some embodiments, circles 32 are posts of metal and area 30 is a surface of, for example, device 10, wavelength converting element 14, or another surface such as a transparent plate to facilitate fabrication of the array or to facilitate spacing the array remotely from device 10 and/or wavelength converting element 14. In some embodiments, area 30 is a surface of a metal layer and circles 32 are holes from which the metal has been removed. The holes may be filled with air or another material such as a dielectric. In some embodiments, elements 32 each have a width between 5 and 500 nm and a height between 5 and 500 nm. Nearest neighbor elements 32 may be spaced between 10 and 1000 nm apart.

The array illustrated in FIG. 7 may be formed by, for example, depositing a lift-off layer, patterning the layer by, for example, optical lithography, e-beam lithography, or nanoimprint lithography, depositing a metal layer such as, for example, silver or gold, then lifting off the lift-off layer to remove excess metal. In some embodiments, the array is formed by a self-assembled block copolymer template. A self-assembled block copolymer template is a polymer that is made up of lengths of two or three different monomers. The different monomers vary in hydrophobicity so they tend to self-assemble into patterns. The copolymer template may be formed on the surface on which the array of nanoparticles is to be formed. A metal layer may be deposited over the template, then the copolymer template is removed, leaving an array of metal nanoparticles. Alternatively, the copolymer template layer may be formed over a metal layer and used as a pattern to etch the metal layer to form the array of nanoparticles.

The array may be configured such that the nanoparticles act as optical resonators or optical antennae, absorbing light and re-emitting it at different angles. The metal nanoparticle arrays may be tuned across the visible range to absorb and re-emit light only in a particular wavelength band by appropriately selecting the particle size and spacing. Such nanoparticle arrays can be designed to have minimum absorption and maximum reflectivity for certain spectral bands. Re-radiation of light by a nanoparticle array may have some dependence of intensity as a function of incidence angle but very little spectral change with incident angle of illumination. The array may be characterized by the diameter d of array elements 32 and the lattice spacing a between neighbor array elements. Though array elements 32 are circular in FIG. 7, any suitable shape including but not limited to ellipses, rectangles, or parallelograms may be used. Though a triangular lattice is illustrated, any suitable lattice including, for example, rectangular, pentagonal, hexagonal, and octagonal lattices, may be used.

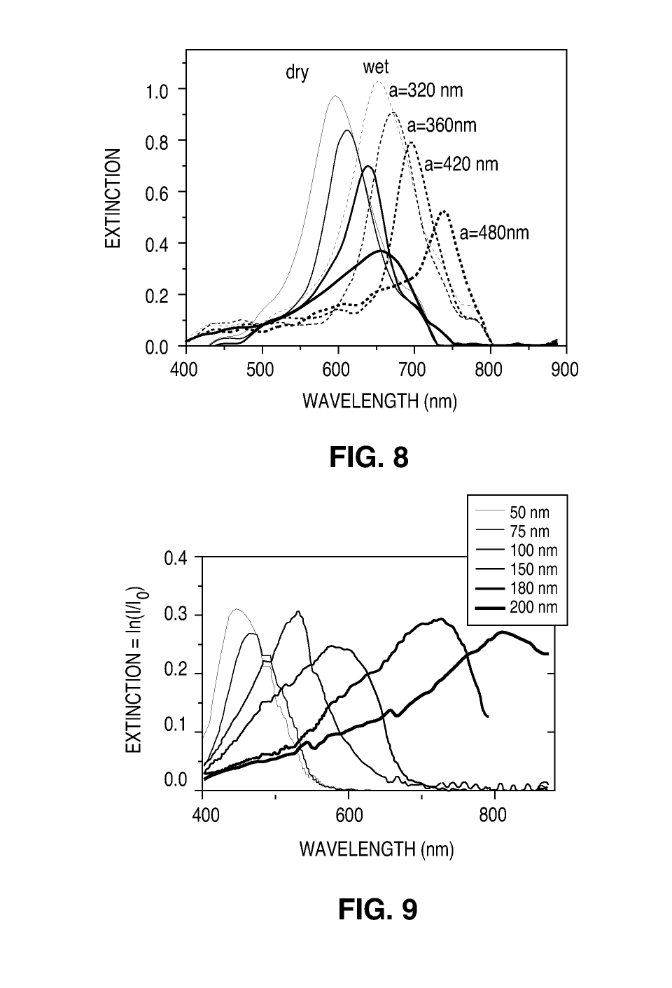

FIG. 8 is a plot of extinction as a function of wavelength for a triangular array of silver nanocylinders 130 nm in diameter and 30 nm tall. The nanocylinders are formed on a quartz surface. Extinction refers to light not passing through the array—light that is extinct is either scattered or absorbed by the array. FIG. 8 illustrates extinction as a function of wavelength for arrays with a lattice spacing of 320 nm, 360 nm, 420 nm, and 480 nm, emitting light into air and into a material with an index of refraction of 1.33 (water). As illustrated in FIG. 8, as the lattice spacing is increased, the peak wavelength of the band of extinct light gets larger—about 600 nm at a=320 nm and 650 nm at a=480 nm when light is extracted into air.

FIG. 9 is a plot of extinction as a function of wavelength for a triangular array of 30 nm tall silver nanocylinders with diameters of 50 nm, 75 nm, 100 nm, 150 nm, 180 nm, and 200 nm. As illustrated in FIG. 9, as the diameter of the array elements increases, the peak wavelength of the band of extinct light gets longer.

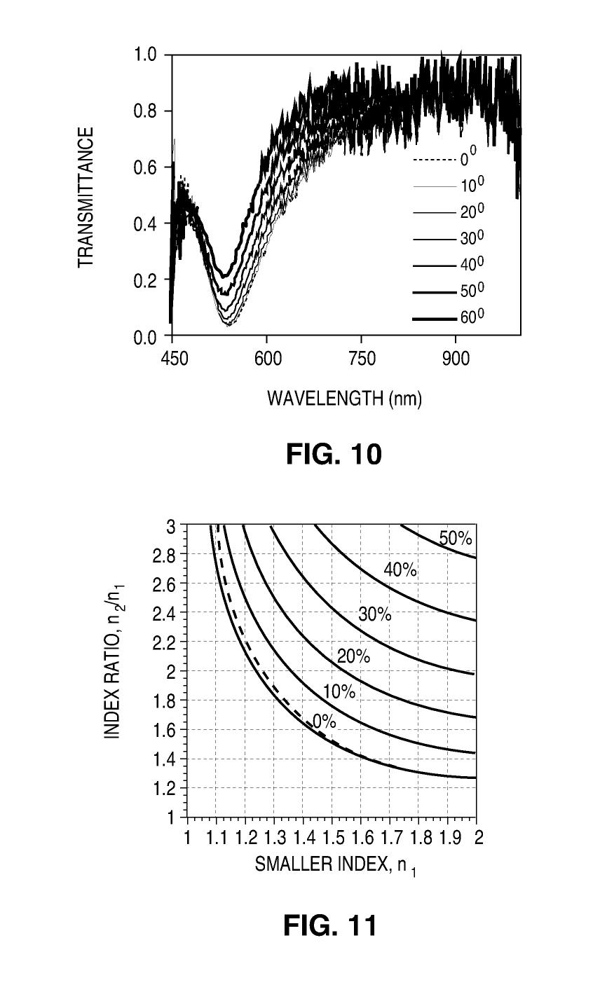

FIG. 10 is a plot of transmittance as a function of wavelength for a gold nanoparticle array for angles of incidence of 0°, 10°, 20°, 30°, 40°, 50°, and 60°. As illustrated in FIG. 10, the wavelength dependence of transmittance is not strongly dependent on the angle of incidence. For example, an angle of 0°, the minimum in the transmittance curve is around 540 nm. At an incident angle of 60°, this transmission minimum has shifted to only 531 nm. In some embodiments, in filter 12 of FIG. 2 or filter 16 of FIG. 3, the filter reflects or absorbs a majority of light in a first wavelength range and passes a majority of light in a second wavelength range. In the second wavelength range, at least 70% of light is passed by the filter regardless of angle of incidence on the filter. In some embodiments, the filter is configured such that the wavelength at which the minimum amount of light is transmitted light shifts no more than 30 nm over the incidence angle range of 0° to 60°.

In some embodiments, a metal nanoparticle array is used in proximity to a quantum dot, phosphor, or other wavelength converting element with a sufficiently small physical thickness (for example, less than 100 nm thick in some embodiments). The strong electric field enhancement present at the metal surface may increase the radiative efficiency of the wavelength converter by decreasing the radiative lifetime of emission from the wavelength converter.

In some embodiments, filter 12 of FIG. 2 or filter 16 of FIG. 3 is a thin film multilayer stack similar to a traditional dichroic filter, but with careful choice of the layer indices to create a wavelength band where light is absorbed or reflected over all angles. An omnidirectional multilayer stack reflector which reflects over the wavelength range 500-750 nm may have in some embodiments a range-midrange ratio of 40%. The “range-midrange ratio” is defined as the ratio (ω₂−ω₁)/0.5(ω₂+ω₁) where ω₂ is the lowest high-frequency photon which is transmitted, and ω₁ is the highest low-frequency photon which is transmitted. The range-midrange ratio defines the refractive indices necessary for omnidirectionality. The difference (ω₂−ω₁) is calculated by identifying the width of the desired “stop band” of the filter, the wavelength band where light is absorbed or reflected over all angles. Frequency is related to wavelength by E=ω/2π=c/λ, where c is the speed of light. Once the range-midrange ratio is calculated, suitable refractive indices can be identified from FIG. 11, which was published as FIG. 4 in Winn et al, Optics Letters 23 (20) 1573-1575, 1998. FIG. 11 is a plot of index ratio n₂/n₁ as a function of smaller index n₁, for a stack of alternating layers of two materials with refractive indices n₁ and n₂.

For a stop band of 500 to 750 nm, one example of a suitable filter is a multilayer stack of materials of refractive index 1.7 and 4.34. To reflect only the narrow light emission of device 10, only a narrow range-midrange ratio of around 10% or less is necessary. This could be achieved with a multilayer film of high and low-index transparent thin films, for example titania and any of a number of transparent thin films with refractive index in the range of 1.4-2 such as, for example, SiO₂. A multilayer stack with a range-midrange ratio of 10% or less may act as a narrow-band omnidirectional filter with minimal loss.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A structure comprising:
a semiconductor light emitting device capable of emitting first light having a first peak wavelength;
a wavelength converting element capable of absorbing the first light and emitting second light having a second peak wavelength; and
a filter comprising a metal nanoparticle array, the metal nanoparticle array comprising an array of areas of a first material separated by a second material, wherein the first material and the second material have different indices of refraction and one of the first material and the second material is metal; wherein
the metal nanoparticle array is configured to pass a majority of light in a first wavelength range and reflect or absorb a majority of light in a second wavelength range.

2. The structure of claim 1 wherein the metal nanoparticle array is disposed between the semiconductor light emitting device and the wavelength converting element.

3. The structure of claim 2 wherein the first wavelength range includes the first light and the second wavelength range includes the second light.

4. The structure of claim 1 wherein the wavelength converting element is disposed between the semiconductor light emitting device and the metal nanoparticle array.

5. The structure of claim 4 wherein the first wavelength range includes the second light and the second wavelength range includes the first light.

6. The structure of claim 1 wherein the first material is metal and the second material is air.

7. The structure of claim 1 wherein the first material is air and the second material is metal.

8. The structure of claim 1 wherein metal comprises at least one of silver and gold.

9. The structure of claim 1 wherein the metal nanoparticle array is configured to pass at least 70% of the light in the first wavelength range regardless of angle of incidence on the metal nanoparticle array.

10. The structure of claim 1 wherein the filter is configured such that a wavelength at which a minimum amount of light is passed by the filter shifts no more than 30 nm for light incident on the filter at angles between 0° and 60° relative to a normal to a major surface of the filter.

11. The structure of claim 1 wherein the areas of first material are metal elements, wherein each metal element has a width between 5 and 500 nm and a height between 5 and 500 nm, and wherein nearest neighbor metal elements are spaced between 10 and 1000 nm apart.

12. A structure comprising:
a semiconductor light emitting device capable of emitting first light having a first peak wavelength;
a wavelength converting element capable of absorbing the first light and emitting second light having a second peak wavelength; and
a filter configured to pass a majority of light in a first wavelength range and reflect or absorb a majority of light in a second wavelength range, wherein the filter is configured such that a wavelength at which a minimum amount of light is passed by the filter shifts no more than 30 nm for light incident on the filter at angles between 0° and 60° relative to a normal to a major surface of the filter.

13. The structure of claim 12 wherein the filter comprises a multilayer stack of materials with different indices of refraction.

14. The structure of claim 13 wherein the multilayer stack comprises titania and a material having an index of refraction of at least 1.4 and no more than 2.

15. The structure of claim 12 wherein the filter is disposed between the semiconductor light emitting device and the wavelength converting element.

16. The structure of claim 15 wherein the first wavelength range includes the first light and the second wavelength range includes the second light.

17. The structure of claim 12 wherein the wavelength converting element is disposed between the semiconductor light emitting device and the filter.

18. The structure of claim 17 wherein the first wavelength range includes the second light and the second wavelength range includes the first light.

19. The structure of claim 12 wherein:
the filter is a metal nanoparticle array;
the wavelength converting element is a ceramic phosphor; and
the filter is disposed between the semiconductor light emitting device and the phosphor.

20. The structure of claim 19 wherein:
the metal nanoparticle array comprises an array of metal elements;
each metal element has a width between 5 and 500 nm and a height between 5 and 500 nm; and
nearest neighbor metal elements are spaced between 10 and 1000 nm apart.
